(19) United States
(12) Patent Application Publication
(10) Pub. No.: US 2013/0062182 A1
(43) Pub. Date: Mar. 14, 2013

(54) TOUCH SWITCH

(71) Applicants: Katsushi TOKURA, Mobara-shi (JP); Eiji MORIMOTO, Mobara-shi (JP)

(72) Inventors: Katsushi TOKURA, Mobara-shi (JP); Eiji MORIMOTO, Mobara-shi (JP)

(21) Appl. No.: 13/611,431

(22) Filed: Sep. 12, 2012

(30) Foreign Application Priority Data
Sep. 12, 2011 (JP) 2011-198593

(51) Int. Cl. H03K 17/98

(52) U.S. Cl. 200/600

(57) ABSTRACT

A touch switch includes a substrate; a sensor unit including a plurality of switch electrodes arranged on the substrate, and switch electrode wirings connected respectively to the corresponding switch electrodes; and a dummy electrode which is arranged on the substrate around the sensor unit and is electrically isolated from the sensor unit. Each of the switch electrodes includes a mark having a planar pattern and a design portion in the planar pattern, and each of the sensor unit and the dummy electrode is formed of a metal thin film.

### FIELD OF THE INVENTION

The present invention relates to a touch switch (also known as a touch key or a touch sensor) for detecting an approach of an operator's finger, hand and the like to a portion corresponding to an electrode based on a change in electrostatic capacitance. More particularly, the present invention relates to a touch switch with a reduced number of parts and a prominent appearance.

### BACKGROUND OF THE INVENTION

A capacitive touch switch is disclosed in Japanese Utility Model Application Publication No. H2-128336. As shown in FIGS. 8A and 8B, the disclosed touch switch includes a manipulation panel 101 having a plurality of contact segments (hereinafter referred to as “key areas”) 102 corresponding to manipulation keys; and a multi-layered substrate 103 which lies beneath the manipulation panel 101 and has conductive patterns 104 stacked in a concentric relationship with the key areas 102, the conductive patterns 104 corresponding to detectors of capacitive switch elements. When a key area 102 on the manipulation panel 101 is touched by an operator's fingertip, a capacitive switch element corresponding to a conductive pattern 104 of the touched key area 102 can be operated.

However, such a conventional touch switch as shown in FIG. 8 has a problem in that the number of parts is increased since it requires the manipulation panel 101 on which certain marks (e.g., 0, #, etc.) of the key areas 102 are formed and the multi-layered substrate 103 on which the conductive patterns 104 corresponding to the detectors of the capacitive switch elements are formed, separately. In addition, there is an additional problem in that the marks of the key areas 102 are abraded due to touch of the key areas 102 by the operator's fingertip, thereby deteriorating the prominent appearance.

### SUMMARY OF THE INVENTION

In view of the above, the present invention provides a touch switch with a reduced number of parts and a prominent appearance. In accordance with an aspect of the present invention, there is provided a touch switch, including a substrate; a sensor unit including a plurality of switch electrodes arranged on the substrate, and switch electrode wirings respectively connected to the corresponding switch electrodes; and a dummy electrode which is arranged on the substrate around the sensor unit and is electrically isolated from the sensor unit, wherein each of the switch electrodes includes a mark having a planar pattern and a design portion in the planar pattern, and each of the sensor unit and the dummy electrode is formed of a metal thin film.

Accordingly, the reduced number of parts can be provided since the electrodes (switch electrodes) are integrated with the marks. In addition, since the sensor unit and the dummy electrode are formed, of the metal thin film, on the substrate, the reduced number of parts can be provided. In particular, when the sensor unit and the dummy electrode are formed of the metal thin film all together (i.e., in the same manufacturing process), they can be manufactured with ease and convenience while reducing costs.

In addition, since the marks are formed of the metal thin film, various shapes of marks can be formed with ease and convenience. Further, since an opposite surface to the surface of the substrate on which the metal thin film is formed is touched by an operator or the like, the marks can have a prominent appearance without being abraded. Moreover, the metal thin film shows a luxurious sense because of its metallic luster, which can obtain a more prominent appearance.

The planar pattern of each of the marks may be formed of a non-open section, and a design portion in the planar pattern may be formed of an open section having a shape corresponding to the design portion.

The planar pattern of each of the marks may be formed of an open section and a non-open section, and a design portion in the planar pattern may be formed of a non-open section having a shape corresponding to the design portion.

Accordingly, various shapes of marks can be formed with ease and convenience since the marks are formed by the open section and the non-open section. In addition, the marks can be formed with ease and convenience to a customer's taste in accordance with whether to provide metallic luster to the marks or to allow of being more noticeable by providing metallic luster to the surroundings of the marks.

An auxiliary electrode may be provided within the open section and connected to the non-open section of the planar pattern.

Accordingly, it is possible to increase the detection areas of the switch electrodes and a change in capacitance in touch detection since the auxiliary electrode is provided within the open sections of the marks.

The planar pattern of each of the switch electrodes may be provided with a plurality of projections formed on its periphery, and the projections may face other switch electrodes, the switch electrode wirings or the dummy electrode.

Accordingly, it is possible to reduce capacitance between conductors since each planar pattern of the switch electrodes is provided with the projections formed on its periphery and the projections face the switch electrode wirings and so on. The dummy electrode may be provided with a plurality of projections which faces the switch electrodes or the switch electrode wirings.

Accordingly, it is possible to reduce capacitance between conductors since the dummy electrode is provided with the projections formed on its periphery and the projections face the switch electrode wirings. A light-shielding insulating member may be provided between at least two of the switch electrodes, between the switch electrodes and the dummy electrode, on the switch electrode wirings and on the dummy electrode.

Accordingly, it is possible to protect the respective electrodes and wirings against a damage caused by exposure and the like since the light-shielding insulating member (non-transparent insulating member) is provided between at least two of the switch electrodes, between the switch electrodes and the dummy electrode, on the switch electrode wirings and on the dummy electrode, except the opening section of the marks through which lights from the light source are transmitted.

A coating film may be provided on an opposite surface to a surface on which the sensor unit of the substrate is formed, the coating film being made of a resin into which beads are mixed, with at least some of the beads being exposed to a surface of the coating film.

Accordingly, a fingerprint made by an operator's touch can be unlikely to be visible, so that reflection by the metal thin film can be prevented, which can result in a prominent appearance, since the coating film made of a resin into which beads are mixed is provided on the opposite surface to the surface on which the sensor unit of the substrate is formed, with at least some of the beads being exposed to the surface of the coating film, and is in a pseudo-etched (diffused surface-reflected) state. In addition, fine unevenness formed on the outer surface of the substrate can improve an operator's touch sense.

A plurality of connection terminals may be provided to connect an external connection member to the switch electrode wirings and the dummy electrode, and all metal thin films on the substrate including the sensor unit, the dummy electrode and the connection terminals may be made of a same metal material.

Accordingly, product costs can be controlled without increasing the number of kinds of materials since all metal thin films on the substrate including the sensor unit, the dummy electrode and the connection terminals are made of the same metal material. In addition, since each of them can be formed of the metal thin film all together (i.e., in the same manufacturing process), it is possible to perform the processes with ease.

The touch switch may further include light sources which are arranged to correspond respectively to the marks to transmit lights through the marks.

Accordingly, the marks can be easily visible and checked since the touch switch further includes the light sources which transmit lights through the marks and are arranged to correspond respectively to the marks. In addition, a form of display of the marks can be selected depending on a customer's taste, in accordance with whether lights are transmitted through the design portion of the marks or the design portion through which lights are not transmitted is allowed of being more noticeable.

The light sources may emit lights of different colors and sequentially change light colors of the switch electrodes decided as being touched.

Accordingly, the marks can be easily visible and checked and the switch electrodes decided as being touched can be easily discerned since the light sources emit lights of different colors and sequentially change light colors of the switch electrodes decided as being touched.

While all of the light sources emit lights of a predetermined color, only a light source corresponding to the switch electrode decided as being touched may emit lights of a different color.

Accordingly, the marks can be easily visible and checked and the switch electrodes decided as being touched can be easily distinguished since, while all of the light sources emitting lights of a predetermined color, only a light source corresponding to the switch electrode decided as being touched emits lights of a different color.

A non-emission member having a color different from that of the metal thin film may be formed on a rear surface of the mark.

Accordingly, the marks can be easily visible and checked since the non-emission member having a color different from that of the metal thin film is formed on the rear surface of the mark.

### BRIEF DESCRIPTION OF THE DRAWINGS

The objects and features of the present invention will become apparent from the following description of embodiments, given in conjunction with the accompanying drawings, in which:

FIG. 1 is a plan view of a touch switch in accordance with an embodiment of the present invention;

FIG. 2 is a cross sectional view of the touch switch, taken along line II-II in FIG. 1;

FIG. 3 is a cross sectional view of the touch switch, taken along line III-III in FIG. 1;

FIGS. 4A to 4C are partially enlarged views of the touch switch shown in FIG. 1;

FIG. 5 is a cross sectional view of the touch switch;

FIG. 6 explains the principle of operation of the touch switch;

FIG. 7 is a circuit diagram of the touch switch; and

FIGS. 8A and 8B show an example configuration of a conventional touch switch.

### DETAILED DESCRIPTION OF THE EMBODIMENTS

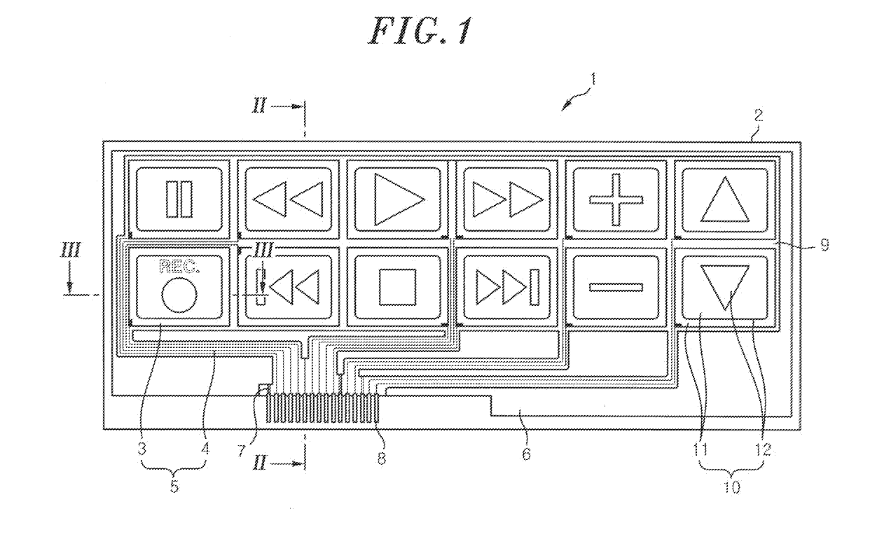

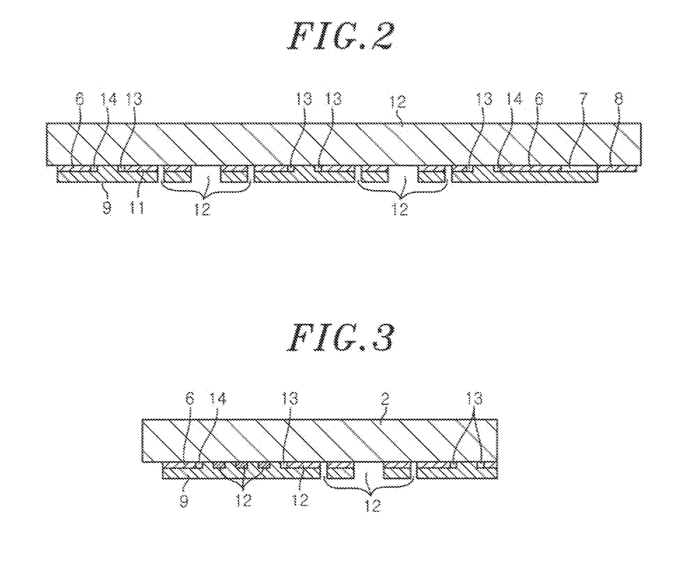

A touch switch in accordance with an embodiment of the present invention will now be described with reference to FIGS. 1 to 7 which form a part hereof. Throughout the drawings, the illustration of certain members which have no direct relationship with the present invention or are not essential to explain the corresponding drawing will be omitted. Further, it is the principle to denote a reference numeral to only one of a plurality of same elements, if any, in the same figure.

As shown in these figures, the touch switch 1 includes a sensor unit 5 including a plurality of switch electrodes 3 and switch electrode wirings 4 each one end of which is connected to the corresponding switch electrode 3; a plurality of dummy electrodes 6; dummy electrode wirings 7 each one end of which is connected to the corresponding dummy electrode 6; and a plurality of connection terminals 8 to which the other ends of the switch electrode wirings 4 and the dummy electrode wirings 7 are connected, all of which are formed (on the same plane) in an inner side of a glass substrate 2. The substrate 2 is not limited to the glass substrate, and may be any transparent or semi-transparent substrate. These electrodes and wirings (the sensor unit 5, the dummy electrodes 6, the dummy electrode wirings 7 and the connection terminals 8) are formed of a metal thin film.

First, e.g., 16 connection terminals 8 are arranged to correspond to the switch electrode wirings 4 and the dummy electrode wirings 7. Each of the connection terminals 8 has one end connected to the corresponding switch electrode wiring 4 or dummy electrode wiring 7 and the other end thereof connected to an external connection member 4. The connection terminals 8 are also arranged parallelly close to one another at one side (lower side) of the circumference of the glass substrate 2. In addition, the switch electrode wirings 4 and the dummy electrode wirings 7 may serve as the connection terminals 8 as well.

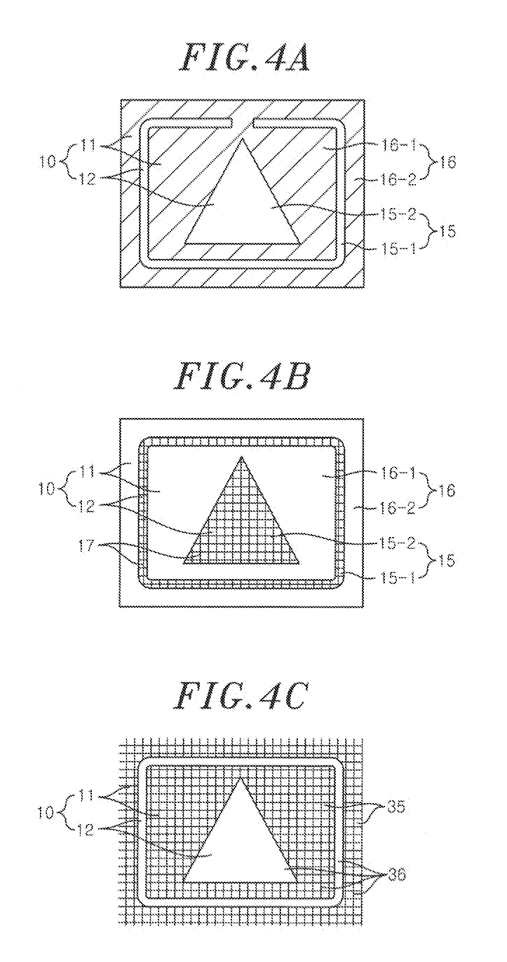

Next, the switch electrodes 3 are arranged regularly with a predetermined interval between neighboring switch electrodes 3. For example, 12 switch electrodes 3 are arranged in a matrix form (6 in column×2 in row) at a central portion of the glass substrate 2, while being electrically isolated from each other. Each of the switch electrodes 3 includes its own mark 10. The mark 10 has a planar pattern 11 and a design portion 12 formed in the planar pattern 11 (see FIGS. 4A to 4C).

The switch electrode 3 and the mark 10 indicate the same member and, in principle, are differently called depending on their functions (i.e., the switch electrode 3 also serves as the mark 10).

For example, 12 switch electrode wirings 4 are arranged to correspond to the 12 switch electrodes 3. In addition, the switch electrode wirings 4 are respectively connected to the connection terminals 8 through gaps between two switch electrodes 3, between two dummy electrodes 6, and between the switch electrodes 3 and the dummy electrodes 6. The switch electrode wirings 4 are preferably formed in a single line to reduce a capacitance and prevent a touch decision from being made by a mistaken touch.

As shown in FIG. 1, a first switch electrode wiring 4 that is located first from the left has one end connected to an upper leftmost switch electrode 3 at a lower left corner thereof and the other end connected to a second connection terminal 8 that is located second from the left.

Likewise, a second switch electrode wiring 4 has one end connected to an upper second-left switch electrode 3 at a lower left corner thereof and the other end connected to a third connection terminal 8 that is located third from the left.

A third switch electrode wiring 4 has one end connected to a lower second-left switch electrode 3 at an upper left corner thereof and the other end connected to a fourth connection terminal 8 that is located fourth from the left.

A fourth switch electrode wiring 4 has one end connected to a lower leftmost switch electrode 3 at a lower left corner thereof and the other end connected to a fifth connection terminal 8 that is located fifth from the left.

A fifth switch electrode wiring 4 has one end connected to a lower third-left switch electrode 3 at a lower right corner thereof and the other end connected to a seventh connection terminal 8 that is located seventh from the left.

A sixth switch electrode wiring 4 has one end connected to an upper third-left switch electrode 3 at a lower right edge thereof and the other end connected to an eighth connection terminal 8 that is located eighth from the left.

A seventh switch electrode wiring 4 has one end connected to an upper fourth-left switch electrode 3 at a lower left corner thereof and the other end connected to a ninth connection terminal 8 that is located ninth from the left.

An eighth switch electrode wiring 4 has one end connected to a lower fourth-left switch electrode 3 at a lower left corner thereof and the other end connected to a tenth connection terminal 8 that is located tenth from the left.

A ninth switch electrode wiring 4 has one end connected to an upper fifth-left switch electrode 3 at a lower left corner thereof and the other end connected to a twelfth connection terminal 8 that is located twelfth from the left.

A tenth switch electrode wiring 4 has one end connected to a lower fifth-left switch electrode 3 at a lower left corner thereof and the other end connected to a thirteenth connection terminal 8 that is located thirteenth from the left.

A eleventh switch electrode wiring 4 has one end connected to an upper rightmost switch electrode 3 at a lower left corner thereof and the other end connected to a fifteenth connection terminal 8 that is located fifteenth from the left.

A twelfth switch electrode wiring 4 has one end connected to a lower rightmost switch electrode 3 at a lower left corner thereof and the other end connected to a sixteenth connection terminal 8 that is located sixteenth from the left.

The dummy electrodes 6 are separated from each other with gaps therebetween and also spaced from the sensor unit 5 at a predetermined interval. For example, 4 dummy electrodes 6 are arranged to surround the sensor unit 5 while being electrically isolated from the sensor unit 5. The dummy electrodes 6 are fixed to a ground potential or a predetermined potential (for example, the same potential as the switch electrodes 3). The dummy electrodes 6 are provided to effectively prevent the sensor unit 5 from malfunctioning by electric charging to an exposed portion of the glass substrate 2 or the like.

In other words, each of the switch electrodes 3 is arranged to face other switch electrodes 3 with gaps therebetween, and the dummy electrodes 6 are arranged to face the outermost perimeter of the group of the 12 switch electrodes 3. With such a configuration, there exist no electrodes with floating potentials around the switch electrodes 3, thereby preventing the malfunction of the sensor unit 5 effectively.

The dummy electrode wirings 7 are arranged to correspond to 4 dummy electrodes 6. Each of the dummy electrode wirings 7 has one end connected to one dummy electrode 6 and the other end connected to one connection terminal 8. Each of the dummy electrode wirings 7 is formed of a plurality of lines, each having a same thickness as that of the switch electrode wiring 4. Each dummy electrode wiring 7 may be formed of a single line which is thicker than that of the switch electrode wiring 4.

One of the four dummy electrodes 6 has a C-like shape and is connected to a first connection terminal 8 that is located first from the left through a corresponding dummy electrode wiring 7. This dummy electrode 6 faces 8 of the 12 switch electrodes 3. That is, this dummy electrode 6 faces 3 two sides of each of the upper leftmost, the upper rightmost, and the lower rightmost switch electrode 3, with a predetermined gap therebetween. Likewise, this dummy electrode 6 faces 5 one side of each of the 4 upper switch electrodes 3, except the upper leftmost and the upper rightmost switch electrode 3 with a gap therebetween, and also faces one side of the lower leftmost switch electrode 3, with the switch electrode wirings 4 interposed therebetween).

One of the 3 remaining dummy electrodes 6 is connected to a sixth-left connection terminal 8 through a corresponding dummy electrode wiring 7. This dummy electrode 6 faces 3 of the 12 switch electrodes 3. That is, this dummy electrode faces 3 one side (lower side) of the bottom first to third switch electrodes 3 from the left with a predetermined gap therebetween.

Another one of the 3 remaining dummy electrodes 6 is connected to an eleventh-left connection terminal 8 through one dummy electrode wiring 7. This dummy electrode 6 faces one of the 12 switch electrodes 3. That is this dummy electrode faces 1 one side (lower side) of the lower fourth-left switch electrode 3 from the left with a predetermined gap therebetween. Likewise, the other of the 3 remaining dummy electrodes 6 is connected to a fourteenth-left connection terminal 8 through a corresponding dummy electrode wiring 7. This dummy electrode faces 1 one side (lower side) of the lower fifth-left switch electrode 3 from the left with a predetermined gap therebetween.

The switch electrode wirings 4 are divided into sets of lines (e.g., two sets of 4 lines and two sets of 2 lines) to be connected to the connection terminals 8 with the dummy electrode wirings 7 interposed therebetween. This configuration can reduce an effect of noises caused by adjacent wirings as compared to the configuration where all the switch electrode wirings 4 are arranged together adjacently to be connected to the connection terminals 8.

The planar pattern 11 of each of the switch electrodes 3 has a plurality of projections 13 formed in its periphery. Each projection 13 of each switch electrodes 3 faces at least one of another switch electrode 3, a switch electrode wirings 4 and a dummy electrode 6. Unless these projections 13 are provided, capacitance between conductors is increased since the gap between each switch electrodes 3 and above-described at least one of another switch electrode 3, a switch electrode wirings 4 and a dummy electrode 6 becomes a band shape having a certain width. On the contrary, when the projections 13 are provided, the capacitance therebetween can be reduced. This makes it possible to improve the precision of a touch decision from a change in capacitance.

Likewise, each of the dummy electrodes 6 has a plurality of projections 14 formed in its periphery. Each projection 14 face at least one of a switch electrodes 3 and a switch electrode wiring 4. This can result in the same effects (reduction in capacitance) as the projections 13 of the switch electrodes 3.

As for the capacitive touch switch, it is preferable that a count value (base capacitance) for a non-touch decision is small while a change rate (change in capacitance) for a touch decision (including a condition where an operator's fingertip is so close to a key area as to be decided as being touched even if the key area is not actually touched by the fingertip) is large. As described above, the reduction of capacitance leads to a decrease in the base capacitance.

An insulating member 9 is placed in order to protect the electrodes and the wirings (particularly the wirings). In particular, if the insulating member 9 has a light-shielding property, it is possible to obtain an effective measure against emission leakage in transmission illumination of the marks 10. The positions of the insulting member 9 to be placed will be described in detail later.

FIGS. 4A to 4C are partially enlarged views showing the touch switch 1. As shown in FIG. 4A, each of the marks 10 of the switch electrode 3 has open sections 15 (exposed portions of the glass substrate 2 in the switch electrodes 3 that are not covered by a metal thin film) and non-open sections 16 (non-exposed portions of the glass substrate 2 in the switch electrodes 3 that are covered by a metal thin film). In FIGS. 4A to 4C, the projections 13 are omitted for the convenience of illustration. FIG. 4A is an enlarged view showing the switch electrode 3 located at the upper right side of the touch switch 1 shown in FIG. 1. FIGS. 4B and 4C illustrate modifications of the switch electrode 3 shown in FIG. 4A. In FIGS. 4A to 4C, the illustration of projections 13 will be omitted.

In FIG. 4A, the planar pattern 11 of the mark 10 included in the switch electrode 3 is formed of a non-open section 16 including non-open sections 16-1 and 16-2. In addition, a design portion 12 in the mark 10 is formed of an open section 15 including open sections 15-1 and 15-2 having shapes corresponding to the design portion 12. The design portion 12 includes a symbol (a triangle in the example of FIG. 4A) formed in the center of the switch electrode 3; and a frame formed therearound. The frame open section 15-1 corresponding to the frame has at least one disconnected portion through which an inner non-open section 16-1 corresponding to an inner side of the planar pattern 11 is connected to an outer non-open section 16-2 that surrounds the frame, the inner non-open section 16-1 being placed between the symbol open section 15-2 corresponding to the symbol and the frame open section 15-1 corresponding to the frame. The outer non-open section is connected to a corresponding switch electrode wiring 4. The reason why this configuration is employed is, for example, that a full frame provides a smaller area serving as the switch electrode 3, which may result in difficulty of a touch decision. If the area of the inner non-open section 16-1 is small, the frame may be entirely connected without any disconnected portion.

FIG. 4B is different from FIG. 4A in that the design portion 12 includes a triangle formed in the center of the switch electrode 3; and a full frame formed therearound, and an auxiliary electrode 17 is provided in the open sections 15-1 and 15-2 to connect the inner open section 16-1 and the outer open section 16-2. This auxiliary electrode 17 allows of an increase in a detection area and improvement in detection sensitivity of a touch made by an operator as compared to a case where the auxiliary electrode 17 is not provided. The auxiliary electrode 17 has either, e.g., a grid pattern or a line pattern.

In FIG. 1C, the planar pattern 11 of the mark 10 is formed of open sections 35 and non-open sections 36. The open sections 35 and the non-open sections 36 may have a grid pattern (a pattern of several lines). The design portion 12 of the mark 10 is formed of non-opening sections 36 having shapes corresponding to the design portion 12. The design portion 12 includes a symbol (e.g., a triangle in this example) formed in the center of the switch electrode 3; and a full frame formed therearound. In such a case, since an electrode exists in the entire surface of the switch electrode 3, a detection area is increased. As a result, the same effects as FIG. 4B can be achieved.

As described above, the insulating member 9 is necessary to protect the electrodes and the wirings, but the insulating member 9 is not formed on the connection terminal 8. When the design portion 12 is formed of open sections 15 as shown in FIGS. 4A and 4B, the insulating member 9 is provided on the switch electrode wiring 4, the dummy electrode wiring 7 and the dummy electrode 6 and portions of the switch electrodes 3 except the design portion 12. Preferably, the insulating member 9 is provided on portions of the glass substrate 2 between two switch electrodes 3 and between the switch electrodes 3 and the dummy electrode 6, and portions on the glass substrate 2 around the switch electrode wiring 4 and the dummy electrode wiring 7.

On the other hand, when the design portion 12 is formed of non-open sections 36 as shown in FIG. 4C, the insulating member 9 is provided only on design portion 12 in the switch electrode 3. In the con figuration example of the touch switch 1 shown in FIG. 1, the glass substrate 2 has a dimension of width of 35 mm, length of 95 mm and thickness of 1.8 mm. The metal thin film has thickness of 1.1 μm. The light-shielding insulating film 9 has thickness of 10 μm.

The switch electrodes 3 have a dimension of width of 15 mm and length of 15 mm. The switch electrode wiring 4 has width of 30 μm. The grid pattern of the planar pattern 11 or the auxiliary electrode 17 has line width of 15 μm and line pitch of 180 μm. The connection terminal 8 has a dimension of width of 4 mm and length of 0.5 mm. The projections 13 of the switch electrode 3 and the projections 14 of the dummy electrode 6 have a dimension of width of 15 μm and length of 15 μm.

A gap between one switch electrode 3 and another and a gap between the switch electrode 3 and the dummy electrode 6 are typically 0.2 mm. A gap between each electrode and each wiring is set to 60 μm to the minimum. A gap between one connection terminal 8 and another is 0.5 mm.

Each of the metal thin films of the touch switch 1 having the above-mentioned dimensionality is formed by forming a film made of a material on the glass substrate 2 by using a sputtering process, a deposition process or a CVD process, exposing and etching the formed film into a predetermined pattern. An example of the material includes aluminum, aluminum alloy (e.g., aluminum-tantalum, etc.) niobium, molybdenum, gold, silver, copper or the like, and the grass substrate 2 is made of soda-lime glass or the like. The light-shielding insulating member (insulating layer) 9 is formed by printing and firing a paste made by mixing a coloring pigment such as a black pigment, a white pigment or the like with a glass frit having a low softening point.

The glass substrate 2 is of transparency. The glass substrate 2 may or may not be colored. The glass substrate 2 has thickness of equal to or less than few millimeters (less than 10 mm), preferably equal to or less than 3 mm from the standpoint of sensitivity of the sensor unit.

The metal thin film has thickness of equal to or less than 2 μm. Although not shown, the metal thin films formed on the glass substrate 2 include an alignment mark, a mark indicating a cut position of the glass substrate, a model name, a lot number and so on.

The metal thin films may be made of different metal materials. However, if all the metal thin films (the connection terminals 8, the sensor units 5, the dummy electrodes 6, the auxiliary electrodes 17 and the dummy electrode wirings 7) are formed by using the same kind of metal material, it is possible to simplify the manufacturing process and reduce the costs. In this case, the same kind of metal material may have a variation of metal composition in the same touch switch during manufacturing process. In addition, if a tempered glass substrate is employed and the manufacturing process is simplified by using the same kind of metal material, it is possible to keep the strength of the tempered glass substrate constant because of the reduced number of times of heating and cooling.

FIG. 5 is a sectional view showing a configuration example where light sources 19 for transmitting lights through marks are arranged in the touch switch 1 (which corresponds to a cross sectional view of the touch switch 1 taken along the line II-II in FIG. 1). FIG. 5 schematically shows only the switch electrode 3 (mark 10) of the metal thin films formed on the glass substrate 2 in the touch switch 1 shown in FIG. 1.

As shown in FIG. 5, tube-like cases 18 are arranged in such a way as to correspond to the switch electrode 3 in the inner side of the glass substrate 2, while being in contact with the switch electrode 3. The cases 18 are made of a light-shielding material. A light source 19 is provided within each of the cases 18. In this example, an LED is used for the light source 19. A diffusion plate 20 is interposed between the LED and the switch electrode 3 to remove the non-uniformity of lights emitted from the LED. The tube-like cases 18 and the light-shielding insulating members 9 serve to prevent the lights emitted from the LED from leaking into regions other than the switch electrodes 3 and thus becoming visible from the outside of the glass substrate 2.

Electrical conduction to the light source 19 is carried out through a printed circuit board 21. It is controlled by the electrical conduction (ON) to and electrical interruption (OFF) from the light source 19 transmits lights through the design portion 12 of the mark 10. In this example, a plurality of sets of the light sources 19, the diffusion plate 20 and the tube-like case 18 is arranged to correspond to the marks 10 (the switch electrodes 3). In this example, 12 light sources are arranged for the marks 10 (in a one-to-one correspondence).

If the design portion 12 is formed of the open sections 15, the design portion 12 appears to be luminous when lights are transmitted through the design portion 12. If the design portion 12 is formed of the non-open sections 16, the design portion 12 through which lights are not transmitted appears to be more noticeable when the lights are transmitted through the open sections 15 in the outside of a contour of the design portion 12. Thus, the mark 10 can be clearly visible.

The touch switch 1 including the printed board 21 and the tube-like cases 18 are actually covered by a body case (not shown). The touch switch 1 is covered by the body case such that regions of the switch electrodes 3 of the touch switch 1 can be externally visible but other regions (the dummy electrodes 6, the connection terminals 8 and so on) cannot be externally visible.

In this example, for the touch switch including light sources shown in FIG. 5, circuit elements such as an LED drive circuit and so on are mounted on the printed board 21, and then, the diffusion plate 20 and the glass substrate 2 are mounted thereon in the tube-like case 18. Various types of circuits which are not mounted on the glass substrate 2 of the touch switch 1 are mounted on the printed board 21, and the connection terminals 8 of the glass substrate 2 are connected to the printed board 21 through a flexible cable 21a and a connector 21b (a member serving to be connected to the external). The connection terminals 8 are connected to the flexible cable 21a using an anisotropic conductive film (not shown) or the like.

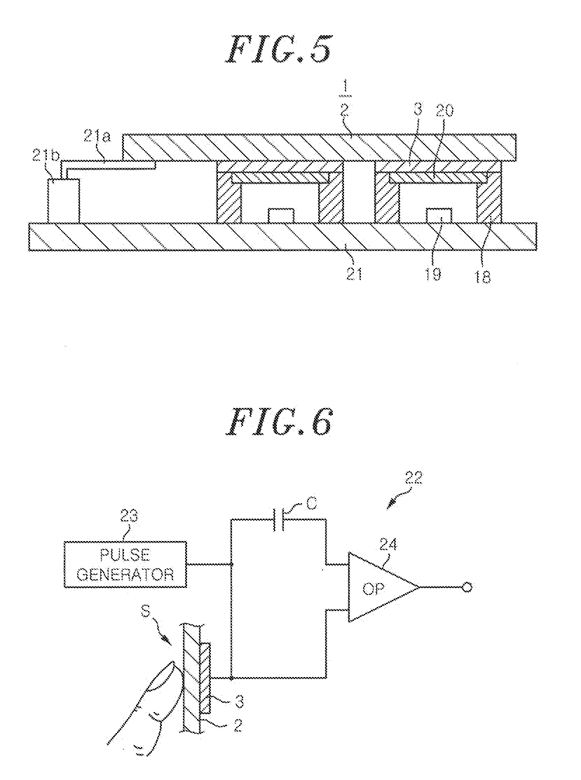

FIG. 6 explains the principle of operation of the touch switch 1 in accordance with the embodiment of the p-resent invention. As shown in FIG. 6, a touch detector 2 includes a pulse generator 23; a comparator 24; and a capacitor C connected between one input of the comparator 24 and the pulse generator 23, and a switch electrode 3 is connected between the pulse generator 23 and the other input of the comparator 24.

When the outer surface (touch portion “S”) of the glass substrate 2 corresponding to the switch electrode 3 is touched by an operator's finger (including a case where the finger is in proximity to the outer surface while the outer surface is not touched by the finger), there occurs capacitance between the finger and the switch electrode 3, which serves as a kind of capacitor. A capacitor “C” having the same capacitance as that of the touch electrode 3 under a non-touch state of the finger is connected between the one input of the comparator 24 and the pulse generator 23.

When the touch portion S is touched by the operator's finger, the touched outer surface of the glass substrate 2 acts as a dielectric substance and the capacitance of the switch electrode 3 is varied. Thus, a capacitance balance between the switch electrode 3 and the capacitor C is collapsed, and thus a difference between pulse voltages applied to both inputs of the comparator 24 is produced to obtain an output from the comparator 24.

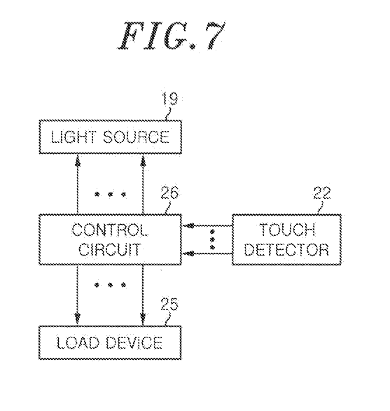

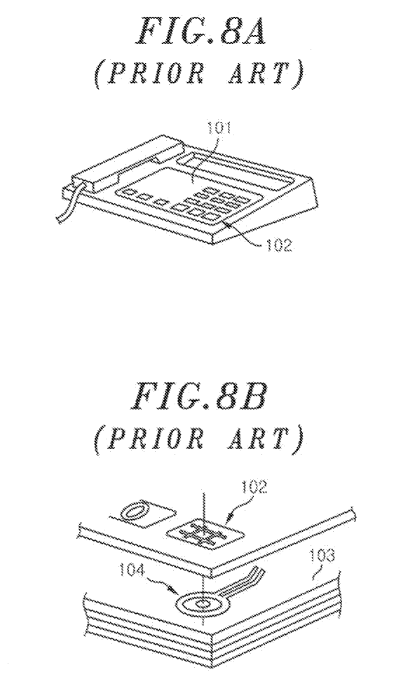

FIG. 7 is a circuit diagram of the touch switch 1 having the light source 19 shown in FIG. 6. As shown in FIG. 7, a circuit of the touch switch 1 includes a touch detector 22 (see FIG. 6) and a control circuit 26 for controlling the light source 19 and a load device 25.

Based on an output from the touch detector 22, the control circuit 26 turns on the light source 19 and the load device 25 corresponding to the switch electrode 3 decided as being touched. Without being limited to this control, the control circuit 26 can freely control a touch operation, On/OFF of the light sources 19 and ON/OFF of the load devices 25, in accordance with conditions, such as types, uses and the like, of the load devices 25.

If the light source 19 can emit lights with different colors (e.g., red, green and blue lights R, G and B), the light color from the light source 19 corresponding to the switch electrode 3 decided as being touched can be sequentially changed (e.g., R→G→B). For example, if the load device 25 is an air conditioner, an audio system or the like, the light color may be changed depending on several phases set for a set temperature, volume or the like.

Moreover, while all light sources 19 emit lights of a predetermined color (e.g., red R) initially, only a light source 19 corresponding to the certain switch electrode 3 decided as being touched may emit lights of a different color (e.g., blue B). Of course, a combination of two light emitting types and other colors than the red and the blue are possible.

Although, in the above-described embodiment, the number of marks 10 of the touch switch 1 is set to be equal to the number of light sources 19, they may be different from each other. For example, if the marks 10 are to be always illuminated, a single light source 19 may be provided for the marks 10. In addition, if a mark 10 has two design portions, two light sources may be provided to emit lights of different colors.

In the above-described embodiment, the light sources 19 have been arranged below the marks 10 of the touch switch 1 for transmission illumination. However, if the surroundings of the touch switch 1 is bright or a separate display is used to display a mark selection, a non-emission member (such as a colored film or the like) colored differently from that of the metal thin film may be adhered to or closely placed in the rear surfaces (surfaces facing the printed circuit board 21) of the marks 10, so that the marks 10 can be more noticeable.

The above-mentioned insulating member 9 may be used for the non-emission member. In this case, the insulating member 9 may be formed on an entire portion of each rare surface (surfaces facing the printed circuit board 21) of the electrodes and wirings, including the marks 10. In addition, a light-shielding insulating member different from the insulating member 9 may be printed and formed.

In the above-described embodiment, no process is performed on the outer surface of the glass substrate 2. However, the outer surface of the glass substrate 2 (an opposite surface to the surface on which the sensor unit 5 and so on are formed) is preferably subjected to a surface treatment.

This surface treatment is carried out by using ink made by mixing various resin beads (e.g., urethane beads or glass beads) into various resins (e.g., epoxy resin). This ink is applied on the outer surface of the glass substrate 2 of the touch switch 1 shown in FIGS. 1 to 7 and then is heated at about 100° and dried, thereby forming a coating film.

This coating film is under a state where beads are dispersed in the resin and at least some beads are exposed to a surface of the coating film. Accordingly, since the outer surface of the glass substrate 2 is in a pseudo-etched (diffused surface-reflected) state, a fingerprint made by an operator's touch is unlikely to be visible and reflection by the metal thin film is prevented, which may result in a remarkable appearance. In addition, fine unevenness of the beads formed on the outer surface of the glass substrate 2 makes it possible to improve an operator's touch sense.

While the invention has been shown and described with respect to the embodiments, it will be understood by those skilled in the art that various changes and modifications may be made without departing from the scope of the invention as defined in the following claims.

What is claimed is:

1. A touch switch, comprising:
a substrate;
a sensor unit including a plurality of switch electrodes arranged on the substrate, and switch electrode wirings respectively connected to the corresponding switch electrodes; and
a dummy electrode which is arranged on the substrate around the sensor unit and is electrically isolated from the sensor unit,
wherein each of the switch electrodes includes a mark having a planar pattern and a design portion in the planar pattern, and
each of the sensor unit and the dummy electrode is formed of a metal thin film.

2. The touch switch of claim 1, wherein the planar pattern of each of the marks is formed of a non-open section, and the design portion in the planar pattern is formed of an open section having a shape corresponding to the design portion.

3. The touch switch of claim 1, wherein the planar pattern of each of the marks is formed of an open section and a non-open section, and the design portion in the planar pattern is formed of a non-open section having a shape corresponding to the design portion.

4. The touch switch of claim 2, wherein an auxiliary electrode is provided within the open section and is connected to the non-open section of the planar pattern.

5. The touch switch of claim 1, wherein the planar pattern of each of the switch electrodes is provided with a plurality of projections formed on its periphery, the projections facing other switch electrodes, the switch electrode wirings or the dummy electrode.

6. The touch switch of claim 1, wherein the dummy electrode is provided with a plurality of projections formed on its periphery, the projections facing the switch electrodes or the switch electrode wirings.

7. The touch switch of claim 1, wherein a light-shielding insulating member is provided between at least two of the switch electrodes, between the switch electrodes and the dummy electrode, on the switch electrode wirings and on the dummy electrode.

8. The touch switch of claim 1, wherein a coating film is provided on an opposite surface of the substrate to a surface on which the sensor unit is formed, the coating film being made of a resin into which beads are mixed, with at least some of the beads being exposed to a surface of the coating film.

9. The touch switch of claim 1, wherein a plurality of connection terminals is provided to connect an external connection member to the switch electrode wirings and the dummy electrode, and the metal thin films on the substrate including the sensor unit, the dummy electrode and the connection terminals are made of a same metal material.

10. The touch switch of claim 1, further comprising light sources which are arranged to correspond to the marks to transmit lights through the marks.

11. The touch switch of claim 10, wherein the light sources emit lights of different colors and sequentially change light colors of the switch electrodes decided as being touched.

12. The touch switch of claim 10, wherein, in a state where all of the light sources emit lights of a predetermined color, a light source corresponding to the switch electrode decided as being touched emits lights of a different color.

13. The touch switch of claim 1, wherein a non-emission member having a color different from those of the metal thin films is formed on a rear surface of the mark.
